(19) United States
(12) Patent Application Publication
(10) Pub. No.: US 2012/0140395 A1
(43) Pub. Date: Jun. 7, 2012

(54) MONITOR WITH RETRACTABLE KEYBOARD

(75) Inventor: HAI-QING ZHOU, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/967,070

(22) Filed: Dec. 14, 2010

(30) Foreign Application Priority Data
Dec. 7, 2010 (CN) 201010577049.5

(51) Int. Cl. H05K 7/14

(52) U.S. Cl. 361/679.09

(57) ABSTRACT

An assembly includes a monitor, a base, a post extending up from the base for supporting the monitor, and a keyboard. The base defines a receiving space for receiving the keyboard.

### BACKGROUND

1. Technical Field

The present disclosure relates to an assembly of a monitor with a retractable keyboard.

2. Description of Related Art

The keyboard of a desktop computer is generally separate from the monitor of the computer. As a result, when the computer is not used, the keyboard is exposed to the environment outside of the computer, occupies a large area on the desktop, and may easily collect dust or other contaminants. Furthermore, liquid may be spilt or is splashed near or on the keyboard, causing damage to the keyboard.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of an assembly of a monitor with a retractable keyboard.

FIG. 2 is an exploded, isometric view of the assembly of FIG. 1.

FIG. 3 is an inverted view of FIG. 2.

FIG. 4 is similar to FIG. 3, but viewed from another perspective.

FIG. 5 is an assembled, isometric view of the assembly of FIG. 4.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

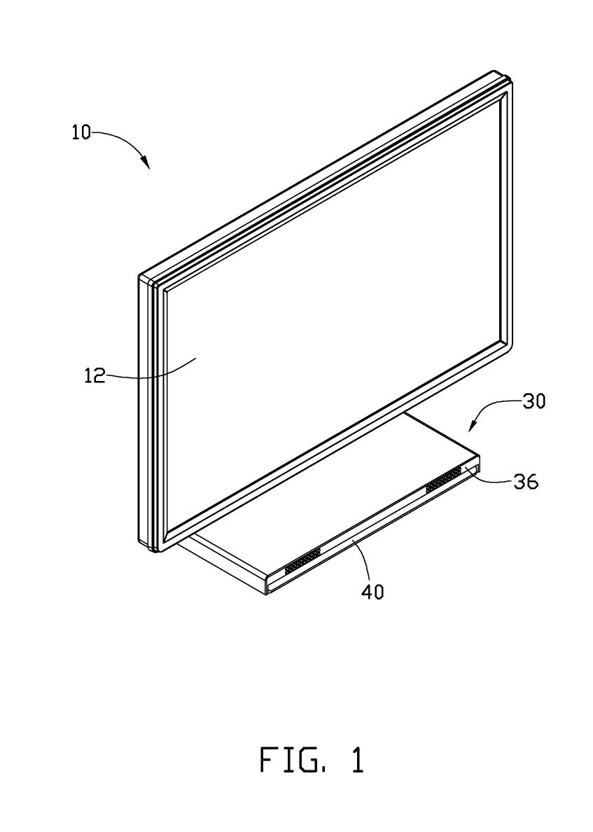

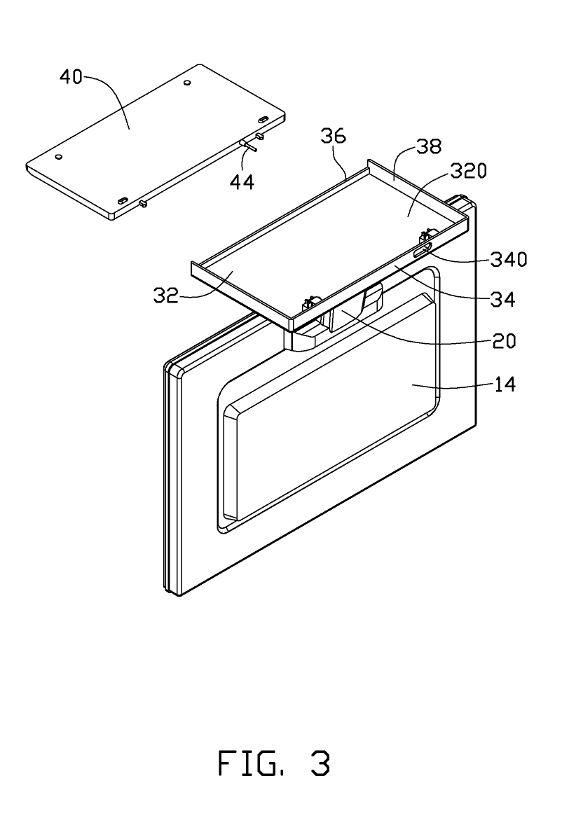

Referring to FIG. 1, an exemplary embodiment of an assembly of a monitor with a retractable keyboard includes a base 30, a post 20 extending up from the base 30 (shown in FIG. 3), a monitor 10 mounted to the post 20 opposite to the base 30, and a keyboard 40.

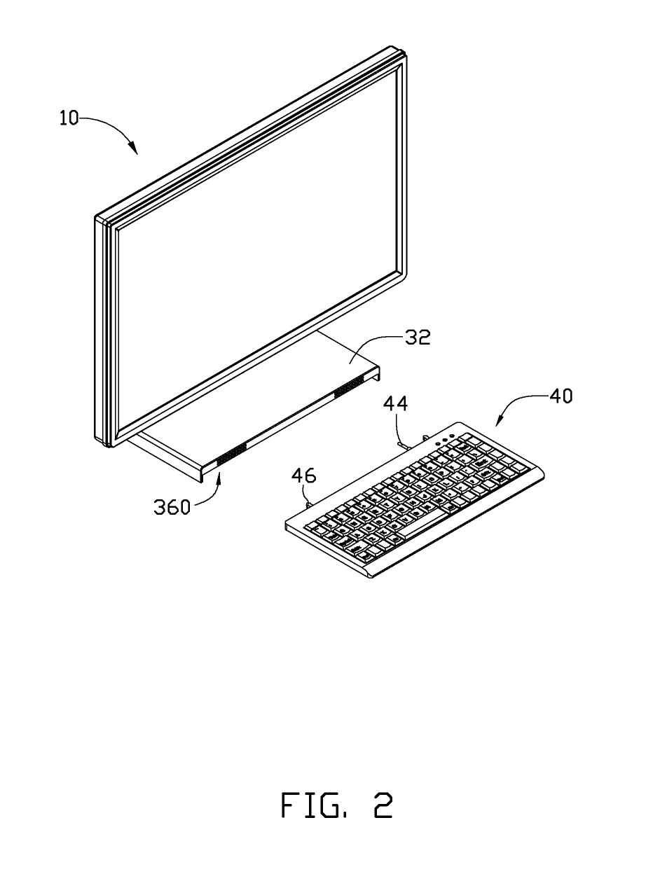

Referring to FIGS. 2 to 4, the monitor 10 comprises a display 12 and an enclosure 14 to hold the display 12.

The base 30 is substantially rectangular-shaped, and includes a top wall 32, a back wall 34, and a front wall 36 substantially perpendicularly extending down from opposite sides of the top wall 32. In addition, two end walls 38 substantially perpendicularly extend down from opposite ends of the top wall 32, with a receiving space 320 bound by the top wall 32, the back and front walls 34, 36, and the end walls 38. An opening 360 and a slot 340 communicating with the receiving space 320 are respectively defined in the front and back walls 36 and 34. Two substantially U-shaped tabs 342 extend forward from opposite ends of the back wall 34. A lock 344 is mounted on a bottom of each tab 342.

Opposite ends of the post 20 are respectively coupled to the top wall 32 of the base 30 and the fixing portion 14 of the monitor 10.

Two latches 46 extend from opposite ends of a back side of the keyboard 40, and a cable 44 extends from the back side of the key board 40 between the latches 46. Each latch 46 can be engaged in a corresponding lock 344. When the latch 46 is pushed towards the lock 344, the latch 46 will engage with the lock 344. When the latch 46 is pushed again, the latch 46 will disengage from the lock 344. The latch and lock mechanism employed herein falls within known technology, and will be illustrated in detail.

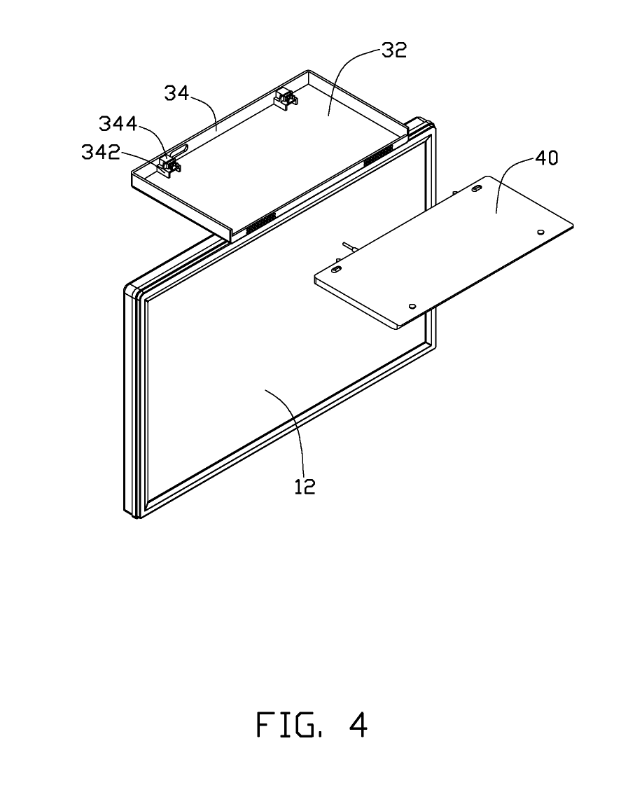

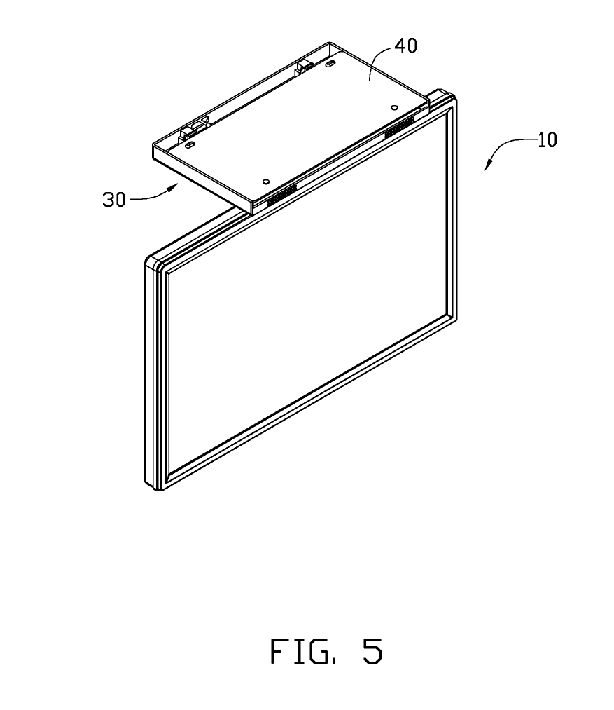

Referring to FIG. 4 and FIG. 5, in assembly, the cable 44 extends through the opening 360 and the slot 340 of the base 30, to be electrically connected to a computer (not shown). The keyboard 40 enters the receiving space 320 of the base 30 through the opening 360, and is pushed toward the back wall 34 of the base 30, until the keyboard 40 is completely received in the receiving space 320. The latches 46 of the keyboard 40 are engaged in the corresponding locks 344 of the base 30.

When retracting the keyboard 40 from the base 30, the keyboard 40 is pushed toward the back wall 34 of the base 30 again, and the latches 46 of the keyboard 40 are disengaged from the corresponding locks 344. Thereby, the keyboard 40 partly moves out from the receiving space 344 by the elastic force of the locks 344.

In other embodiments, the front wall 36 of the base 30 may be omitted.

In other embodiments, the locks 344 may be omitted, too. In this embodiment, a gap is defined in a front end of each end wall 38 of the base 30 adjacent to the front wall 36. In use, the keyboard 40 can be moved out of the receiving space 320 with fingers entering the corresponding gaps to operate opposite ends of the keyboard 40.

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. An assembly, comprising:
a monitor;
a keyboard;
a base defining a receiving space to accommodate the keyboard; and
a post extending up from the base to support the monitor.

2. The assembly of claim 1, wherein the base comprises a top wall, a back wall and a front wall extending down from back and front sides of the top wall, and two end walls extending down from opposite ends of the top wall, wherein the receiving space is bounded by the top wall, the back and front walls, and the end walls.

3. The assembly of claim 2, wherein the front wall defines an opening communicating with the receiving space, through which the keyboard enters the receiving space.

4. The assembly of claim 2, wherein a latch extends from a back side of the keyboard, a lock is mounted to an inner side of the back wall of the base, to engage with the latch of the keyboard in response to the keyboard being completely received in the receiving space.

5. The assembly of claim 1, wherein the base comprises a top wall, a back wall extending down from a rear side of the top wall, and two end walls extending down from opposite ends of the top wall, wherein the receiving space is bounded by the top wall, the back wall, and the end walls, the base defines an opening communicating with the receiving space, opposite to the back wall, through which the keyboard enters the receiving space.
